(19) United States
(12) Patent Application Publication
(10) Pub. No.: US 2007/0113137 A1
(43) Pub. Date: May 17, 2007

(54) Error Correction in Binary-encoded DNA Using Linear Feedback Shift Registers

(76) Inventor: Ho Seung Ryu, Pacific Grove, CA (US)

Correspondence Address: HO SEUNG RYU, 1042 FOREST AVE., APT. 3, PACIFIC GROVE, CA, 93950-4830, US

(21) Appl. No.: 11/163,549

(22) Filed: Oct. 22, 2005

(51) Int. Cl. H04L 1/00; H03M 13/00; G08C 25/00; G06F 11/00; G06F 11/30

(52) U.S. Cl. 714/746

(57) ABSTRACT

An encoding method for binary data storage in DNA that makes possible the correction of common errors that occur in strands of DNA. A linear feedback shift register generates a long sequence of bits used for the correction of DNA-specific errors.

### THE FIELD OF THE INVENTION

The field of the invention is error correction and, more particularly, the repair of common errors in the storage of binary data in DNA.

### BACKGROUND OF THE INVENTION

Data storage capacity has increased dramatically in recent decades, so quickly that computer components may become the size of molecules in the future. As data density reaches such levels, suitable means for storing huge quantities of data in a stable structure are needed. A solution to this problem is the organic molecule deoxyribonucleic acid (DNA), perhaps the ultimate data storage structure. DNA is capable of providing a stable and compact medium for data storage.

Currently, it is possible to assemble a molecule of DNA from a string of bases. Likewise, it is possible to read and recover the base sequence from a given DNA fragment. With these tools, any desired information could be stored in DNA. In the write phase, information is converted into a sequence of bases, which are then assembled into DNA molecules. In the store phase, the DNA remains in storage, not interacting with the outside world in any meaningful fashion. Then, in the read phase, the sequence of bases in the DNA is read and interpreted.

To ensure that the data recovered in the read phase and data stored in the write phase are identical, error correction methods are needed. However, traditional error correction methods are inadequate for data storage in DNA, since strands of DNA are known to sustain mutations such as translocation, inversion, insertion, and deletion, which are not normally observed in traditional forms of data storage. Although organisms often use enzymes to correct errors and perform many other tasks, it is desirable to have methods that rely strictly on the base sequences of DNA fragments in storage so that integrity may always be guaranteed.

### DESCRIPTION OF THE INVENTION

The encoding method of the present invention provides detection and repair mechanisms for the common errors that occur in DNA. Using this method, any binary information could be encoded into a sequence of bases, which could then be assembled into a strand of DNA and placed in storage. At a later date, the sequence of bases could be read from the strand of DNA, and then decoded to recover the original binary information, using error correction techniques as described in this document.

Three Levels of Structure

To provide for such error correction techniques, sequences of DNA bases are analyzed. There are four possible bases in DNA: adenine (A), cytosine (C), guanine (G), and thymine (T). Each base corresponds to a pair of two binary digits, which are hereafter referred to as the head and the tail bits. The following is one possible mappings of bases:
adenine: head bit 0, tail bit 0
cytosine: head bit 0, tail bit 1
guanine: head bit 1, tail bit 1
thymine: head bit 1, tail bit 0

This particular mapping is notable in that the base pairs (A/T and C/G) share the same tail bit. Given a sequence of n bases, S={b₁, b₂, . . . bₙ}, the head bits form the sequence Sₕ={h₁, h₂, . . . hₙ} and the tail bits form Sₜ={t₁, t₂, . . . tₙ}. Therefore, given a sequence of head bits and a concurrent sequence of tail bits, there is a corresponding sequence of bases. Conversely, a sequence of bases can be made into a sequence of head bits and a concurrent sequence of tail bits. The relationship between the base sequence and the corresponding concurrent head and tail sequences form the first level of structure for the encoding method described in this document.

For the second level of structure, linear feedback shift registers are used to generate a long sequence of bits to fill the tail sequence. A linear feedback shift register (LFSR), used in encryption and random number generation, can be used to provide long sequences of bits. From a seed of n bits, an LFSR can generate a repeating sequence of bits with a period up to 2ⁿ−1. A linear shift feedback register has a state of n-bits: {b₁, b₂, . . . bₙ}. From there, the exclusive or operation is applied to bits at specific positions, known as tap locations, to generate another bit. Then, the new bit placed at the very right of the state, to form {b₁, b₂, . . . bₙ, bₙ₊₁}, and then the bit at the left is removed, to create the new state of {b₂, b₃, . . . bₙ₊₁}. This shifting process is then repeated as long as needed. The state can never consist of all zeroes, since such a state just generates an infinite string of zero bits.

For any n, a proper set of tap locations can create an LFSR that generates a bit sequence with a period of 2ⁿ−1. Used as the tail bit sequence with information to be stored making up the head bit sequence, the LFSR bits create a kind of a unique signature that makes some error detection and correction possible. Given the starting state of the LFSR and the tap locations, the expected tail bit sequence can be generated and compared to the actual stored tail bit sequence. Any discrepancy between the expected and the observed bit sequences would indicate that an error has occurred.

In case of errors, it is useful to note that the state of a maximal-period LFSR goes through all the possible bit sequences of length n, except for one in which all the bits are zero. In other words, any fragment of length n or more can be placed in its proper place in the bit sequence. Therefore, given a base sequence in which the tail sequence contains bits from that LFSR, the sequence can be reconstructed even it is divided into several fragments.

Now, the LFSR bits serve another purpose. DNA is normally double-stranded, with only one strand that is actually transcribed and translated, which will be referred to as the active strand. The complementary strand only exists for structural and replication purposes. Using the LFSR bits allows for the determination of the active strand. Using the mapping given in which the base pairs share the same tail bit, the active strand would have its tail bits follow the bits generated from the given LFSR, and the complementary strand would have its tail bits be in reverse order as they would be if generated from the LFSR. It can be shown that a bit sequence from a maximal-period LFSR and its reverse sequence cannot have 2n or more consecutive bits in common.

One of the errors that can occur in DNA in the store phase is inversion, in which part of a DNA is turned 180 degrees and placed back into sequence somewhere. Although this error would cause traditional methods of error correction to fail, the linear feedback shift register handles it with no problems. In fact, using the LFSR, the places where the DNA fragment was broken can be found. Once the fragments have been found, finding the correct ordering of the fragments is a simple matter of determining the active strands and finding where they belong by analyzing the tail bits.

Using tail bits, many of the errors can be corrected. However, a number of problems still remain. There are certain “holes” left behind by piecing together fragments via LFSR. Indeed, a number of bases may be missing or incorrect where fragments are joined. In addition, it is too much to create new fragments for a single bit error. A certain threshold for bit-level errors must be established, whereby a single bit error is not enough to create a new fragment. An error of one bit per 2n bits is a good threshold.

In the end, the head bit sequence itself needs to have some sort of error correction information. With the head bit sequence, the method used to fix the errors is simply a use of standard error correction, consisting of repairing the bits that are either missing or wrong. With the linear feedback shift registers removing all but small errors, a powerful error correction such as the Reed-Solomon algorithm works well.

DNA and Error Correction

When errors occur in DNA, most are promptly corrected or destroyed, but some remain and may have visible consequences. Some common errors that may occur are point substitution, insertion, deletion, inversion, and translocation. Point substitution is the replacement of a single base by another base. Insertion or deletion of nucleotides involves arbitrary addition or removal of nucleotides and can cause the protein translation processes to become misaligned, with often devastating results to the data in storage. Translocation occurs as parts of DNA dislodge and reinsert themselves at different places in the DNA. Inversion occurs when a detached fragment flips 180 degrees and is reinserted into the DNA while still inverted. Such changes occur rather seldom in DNA but frequently enough to be noticeable, even in living organisms. Remarkably, a DNA molecule that has been modified through translocation, point substitution, and other such processes may not betray any signs of having been altered. In the end, the integrity of the data stored in DNA must be guaranteed through examining only the sequence of bases.

The errors that need to be addressed by the error correction method are point substitution, insertion, deletion, inversion, and translocation. Almost all of these errors can be detected by the linear feedback shift register bits, since insertion, deletion, inversion, and translocation all cause errors in the tail bits. The linear feedback shift registers handle reordering of fragments. Then, the rest of the work is performed with a powerful error correction system, such as the Reed-Solomon algorithm.

This type of error correction is unprecedented, in that traditional error correction in computers generally involves correcting certain missing or damaged bits. In a hard drive, a cluster of data does not spontaneously jump to another region or get inverted under any normal storage conditions. In DNA, both types of errors occur, as well as others. DNA-specific errors are addressed using linear feedback shift registers, dividing the input into fragments, which are then joined together. After processing by the linear feedback shift register, the output is friendly to traditional error correction algorithms, which can correct the rest of the remaining errors.

Therefore, the encoding method for binary data storage in DNA as described in this document makes possible the correction of common errors that occur in DNA used for long-term data storage.

What is claimed is:

1. In a system for preparing binary data for storage in DNA, a method for encoding two concurrent sequences of bits into a single sequence of bases.

2. The encoding method of claim 1, wherein the two concurrent sequences of bits consist of one sequence of bits representing the binary data to be stored in DNA, and the other containing bits from a linear feedback shift register.

3. An encoding method for binary data storage in DNA that makes possible the correction of common errors that occur in strands of DNA. A linear feedback shift register generates a long sequence of bits used for the correction of DNA-specific errors.
